(19) United States
(12) Patent Application Publication
(10) Pub. No.: US 2015/0311042 A1
(43) Pub. Date: Oct. 29, 2015

(54) SUBSTRATE TREATING APPARATUS

(71) Applicant: PSK INC., Hwaseong-si (KR)

(72) Inventor: Dae-Hee SON, Hwaseong-si (KR)

(21) Appl. No.: 14/582,575

(22) Filed: Dec. 24, 2014

(30) Foreign Application Priority Data
Apr. 29, 2014 (KR) 10-2014-0051901

(51) Int. Cl. H01J 37/32

(52) U.S. Cl. CPC H01J 37/32798

(57) ABSTRACT

Provided is a substrate treating apparatus which treats a substrate using plasma. The substrate treating apparatus includes a processing chamber having an inner space in which process treatment is performed on a substrate, a cover member coupled to the processing chamber by a hinge part and rotating upwardly and downwardly with respect to the hinge part to open/close the processing chamber, and a close preventing member disposed on a sidewall of the cover member to prevent the cover member from being closed during upward rotation of the cover member.

The substrate treating apparatus prevents a cover member opening/closing a processing chamber from being sudden closed to secure operator's safety.

### CROSS-REFERENCE TO RELATED APPLICATIONS

This U.S. non-provisional patent application claims priority under 35 U.S.C. §119 of Korean Patent Application No. 10-2014-0051901, filed on Apr. 29, 2014, the entire contents of which are hereby incorporated by reference.

### BACKGROUND OF THE INVENTION

The present invention disclosed herein relates to a substrate treating apparatus, and more particularly, to a substrate treating apparatus using plasma.

Manufacturing a semiconductor device requires various processes such as deposition, photolithography, etching, ashing, cleaning, and polishing. Many processes such as deposition, etching, and ashing use plasma to treat a semiconductor substrate such as a wafer.

A substrate treating apparatus using plasma includes a chamber providing a space in which a substrate treating process is performed, and a plasma generation unit disposed above the chamber. A cover member opening/closing the chamber is disposed on an upper end of the chamber for maintenance, etc.

The cover member is configured such that one or more operators manually open/close the cover member by using an upper lid handle. When an operator does not notice that another operator closes the cover member during opening/closing of the cover member by hands, it is possible that safety accident may occur.

### SUMMARY OF THE INVENTION

The present invention provides a substrate treating apparatus preventing a cover member from being suddenly closed to secure operator's safety.

The present invention also provides a substrate treating apparatus having a close preventing member with a simplified structure to promote operation convenience and also prevent in advance an accident caused by missing of safety apparatus operation.

The object of the present invention is not limited to the aforesaid, but other objects not described herein will be clearly understood by those skilled in the art from descriptions below.

Embodiments of the present invention provide substrate treating apparatuses including: a processing chamber having an inner space in which process treatment is performed on a substrate; a cover member coupled to the processing chamber by a hinge part and rotating upwardly and downwardly with respect to the hinge part to open/close the processing chamber; and a close preventing member disposed on a sidewall of the cover member to prevent the cover member from being closed during upward rotation of the cover member.

In some embodiments, the close preventing member may have a lower end which is provided at a position where it overlaps an upper wall of the processing chamber when viewed from the top.

In other embodiments, the close preventing member may have an end which is pin-connected to a sidewall of the cover member, and the other end provided as a free end.

In still other embodiments, the close preventing member may include a body part providing the end, and a supporting part providing the other end.

In even other embodiments, the close preventing member may be convertible between a first state where the supporting part is disposed above the body part and a second state where the supporting part is disposed below the body part, wherein the conversion from the first state to the second state is performed by rotation of the close preventing member with respect to the hinge part by gravity.

In yet other embodiments, the close preventing member may be provided vertically to a horizontal plane in the second state, and a rotational angle of the close preventing member between the first state and the second state may be greater than 180° and is equal to or less than 270°.

In further embodiments, the close preventing member may further include, between the first state and the second state, a third state where the close preventing member is disposed horizontally to a sidewall of the cover member, when the cover member completely rotates downwardly to close the processing chamber.

In still further embodiments, the close preventing member may be converted from the second state to the first state before downward rotation of the cover member, maintain the first state during the downward rotation of the cover member, and be converted from the first state to the third state when the downward rotation of the cover member is completed to close the processing chamber.

In even further embodiments, the conversion from the second state to the first state may be performed by external force.

In yet further embodiments, the sidewall of the cover member may be provided such that an area provided with the close preventing member is more recessed inwardly than an area corresponding to the hinge part.

In other embodiments of the present invention, the substrate treating apparatuses include: a first stopper restricting rotational range allowing the close preventing member to rotate until the first state when the cover member rotates downwardly to close the processing chamber; and a second stopper restricting rotational range allowing the close preventing member to rotate until the second state when the cover member rotates upwardly to open the processing chamber.

In some embodiments, the first stopper and the second stopper may be provided on the sidewall of the cover member.

In other embodiments, the first stopper may be provided vertically to a top surface of the cover member, and the second stopper may extend from a lower end of the first stopper, wherein an angle between the first stopper and the second stopper according to a rotational direction of the close preventing member may be greater than 180° and is equal to or less than 270°.

In still other embodiments, the supporting part may be detachably coupled to the body part.

In even other embodiments, the body part may be made of a material greater in strength than the supporting part.

In yet other embodiments, the body part may be made of stainless steel and the supporting part may be made of Teflon.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view of a substrate treating apparatus according to an embodiment of the present invention;

FIG. 2 is a perspective view illustrating a cover member in FIG. 1 being opened;

FIG. 3 is a perspective view illustrating a coupling configuration of a close preventing member in FIG. 2;

FIG. 4 is a perspective view of the close preventing member in FIG. 3;

FIG. 5 is a side view illustrating a first state of the close preventing member in FIG. 2;

FIG. 6 is a side view illustrating a second state of the close preventing member in FIG. 2;

FIG. 7 is a perspective view of FIG. 6;

FIG. 8 is a side view illustrating a third state of the close preventing member in FIG. 2;

FIG. 9 illustrates a stopper in FIG. 3;

FIGS. 10 to 12 illustrate how a close preventing member is operated during opening of a cover member; and

FIGS. 13 to 17 illustrate how a close preventing member is operated during closing of a cover member.

### DETAILED DESCRIPTION OF PREFERRED EMBODIMENTS

Hereinafter, preferred embodiments of the present invention will be described below in more detail with reference to the accompanying drawings. In the figures, the dimensions of layers and regions may be exaggerated for clarity of illustration. Note that the same or similar components in the drawings are designated by the same reference numerals as far as possible even if they are shown in different drawings. In the following description of the present invention, a detailed description of known functions and configurations incorporated herein will be omitted to avoid making the subject matter of the present invention unclear.

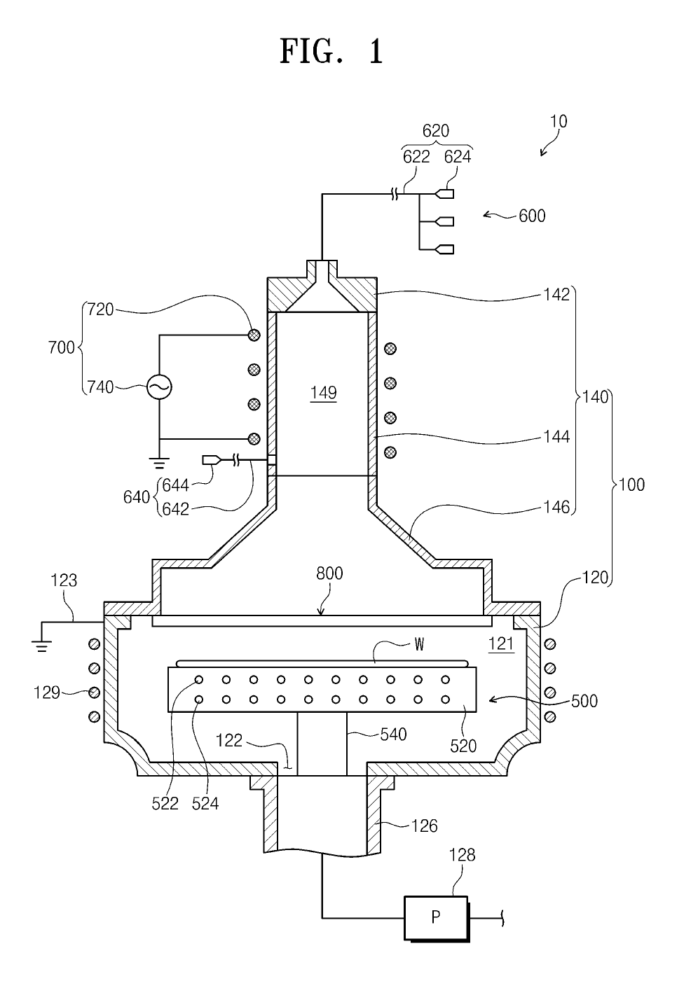

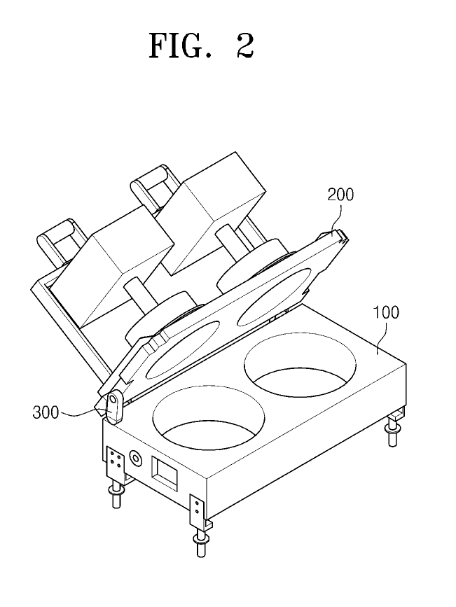

FIG. 1 is a cross-sectional view schematically illustrating a substrate treating apparatus according to an embodiment of the present invention, and FIG. 2 is a perspective view illustrating a cover member in FIG. 1 being in an opened state.

Referring to FIGS. 1 and 2, a substrate treating apparatus 10 etches a thin film on a substrate W using plasma. The thin film may be various kinds of films such as a polysilicon film, a silicon oxide film, and a silicon nitride film. Also, the thin film may be a natural oxide film or a chemically generated oxide film.

The substrate treating apparatus 10 includes a processing chamber 100, a cover member 200, a close preventing member 300, a supporting unit 500, a gas supply unit 600, a plasma source 700, and a baffle 800.

The processing chamber 100 has an inner space in which process treatment is performed on the substrate W. The processing chamber 100 includes a treatment chamber 120 and a plasma generation chamber 140. The treatment chamber 120 provides a space 121 for treating a substrate W by plasma. The plasma generation chamber 140 provides an inner space 149 in which plasma is generated from a processing gas.

The treatment chamber 120 has the space 121 therein of which an upper portion is opened. The treatment chamber 120 may have a substantially cylindrical shape. The treatment chamber 120 has an exhaust hole 122 provided in a bottom surface thereof. An exhaust line 126 is connected to the exhaust hole 122. A pump 128 is installed on the exhaust line 126. The pump 128 adjusts an inner pressure of the treatment chamber 120 to a processing pressure. Residual gas and by-products in the treatment chamber 120 are discharged to the outside of the treatment chamber 120 through the exhaust line 126. A wall-heater 129 may be provided on an outer side of the treatment chamber 120.

The plasma generation chamber 140 is disposed outside the treatment chamber 120. According to an example, the plasma generation chamber 140 is disposed on and coupled to the treatment chamber 120. The plasma generation chamber 140 includes a gas port 142, a discharge chamber 144, and a diffusion chamber 146. The gas port 142, the discharge chamber 144, and the diffusion chamber 146 are sequentially provided from top to bottom. The gas port 142 receives a gas from the outside. The discharge chamber 144 has a hollow cylindrical shape. When viewed from the top, the inner space 149 of the discharge chamber 144 is smaller than the inner space 121 of the treatment chamber 120. Plasma is generated from the gas in the discharge chamber 144. The plasma generated in the discharge chamber 144 is supplied to the treatment chamber 120 through the diffusion chamber 146. The diffusion chamber 146 has an inner space which is gradually widened from top to bottom. A lower end of the diffusion chamber 146 is coupled to an upper end of the treatment chamber 120, and a sealing member (not shown) is provided therebetween for sealing from the outside.

The processing chamber 100 is made of a conductive material. The processing chamber 100 may be grounded through a ground line 123.

The supporting unit 500 supports the substrate W. The supporting unit 500 includes a supporting plate 520 and a supporting shaft 540. The supporting plate 520 is disposed in the inner space 121 and has a disc shape. The supporting plate 520 is supported by the supporting shaft 540. The substrate W is placed on an upper side of the supporting plate 520. An electrode (not shown) is provided in the supporting plate 520 and the substrate W is supported by the supporting plate 520 through an electrostatic force. A heating member 522 may be provided in the supporting plate 520. According to an example, the heating member 522 may be a heating coil. Also, a cooling member 524 may be provided in the supporting plate 520. The cooling member 524 may be provided as a cooling line through which a coolant flows. The heating member 522 heats the substrate W to a predetermined temperature, and the cooling member 524 forcibly cools down the substrate W.

The gas supply unit 600 includes a first gas supply unit 620 and a second gas supply unit 640.

The first gas supply unit 620 includes a first gas supply line 622 and a first gas storage 624. The first gas supply line 622 is connected to the gas port 142. A first gas supplied through the gas port 142 is introduced into the discharge chamber 144 to be excited to plasma in the discharge chamber 144. The first gas may include difluoromethane (CH₂F₂), nitrogen (N₂), and oxygen (O₂). Optionally, the first gas may further include different kinds of gases such as tetrafluoromethane (CF₄).

The second gas supply member 640 includes a second gas supply line 642 and a second gas storage 644. The second gas is supplied onto a path through which the plasma generated from the first gas is introduced to the treatment chamber 120. According to an example, the second gas supply line 642 is connected to the discharge chamber 144 in a lower portion than an antenna 720 which will be described later. The second source gas may include nitrogen trifluoride (NF₃).

According to the above-described configuration, the first gas is directly excited to plasma by electric power, and the second gas is excited to plasma through reaction with the first gas.

In the above-described example, the first and second gases may be variously changed in type. Also, only the first gas supply member 620 may be provided, without providing the second gas supply member 640.

The plasma source 700 generates plasma from the first gas in the discharge chamber 144. According to an example, the plasma source 700 may be an inductively coupled plasma source 700. The plasma source 700 includes an antenna 720 and a power supply 740. The antenna 720 is provided outside the discharge chamber 144 and winds the discharge chamber 144 several times. The antenna 720 has one end connected to the power supply 740 and the other end connected to the ground. The power supply 740 applies electric power to the antenna 720. According to an example, the power supply 740 may apply high-frequency power to the antenna 720.

A baffle 800 is disposed between the treatment chamber 120 and the plasma generation chamber 140. The baffle 800 uniformly maintains the density and flow of plasma over a whole area in the treatment chamber 120 when the plasma is supplied to the substrate W. The baffle 800 is grounded. According to an example, the baffle 800 may be in contact with the processing chamber 100 and connected to the ground through the processing chamber 100. Alternatively, the baffle 800 may be directly connected to an additional ground line. Accordingly, the baffle 800 supplies radicals to the treatment chamber 120 and prevents ions and electrons from being introduced into the treatment chamber 120. The baffle 800 is fixed to the processing chamber 100. According to an example, the baffle 800 may be coupled to a lower end of the plasma generation chamber 140.

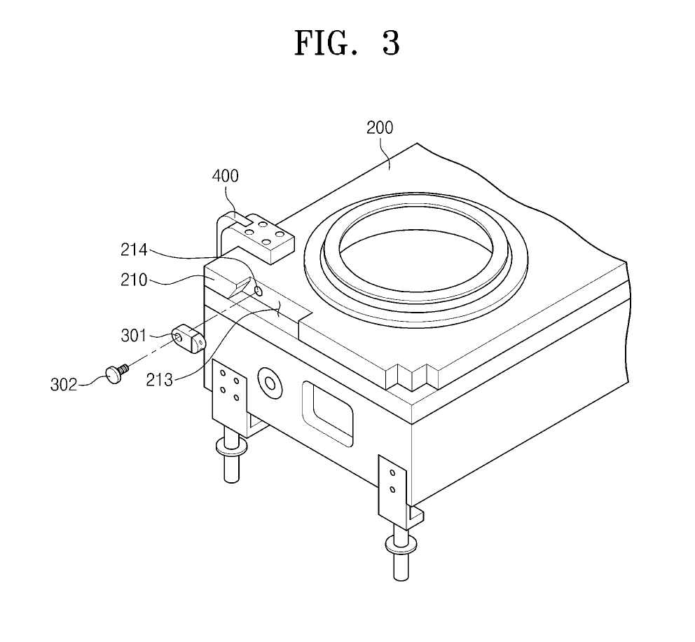

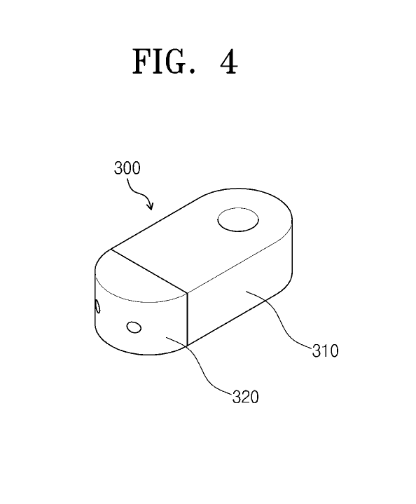

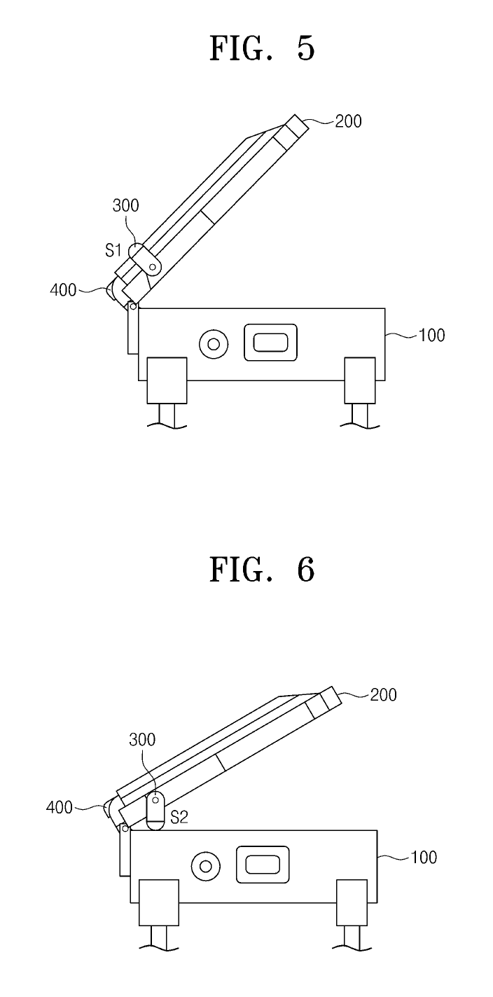

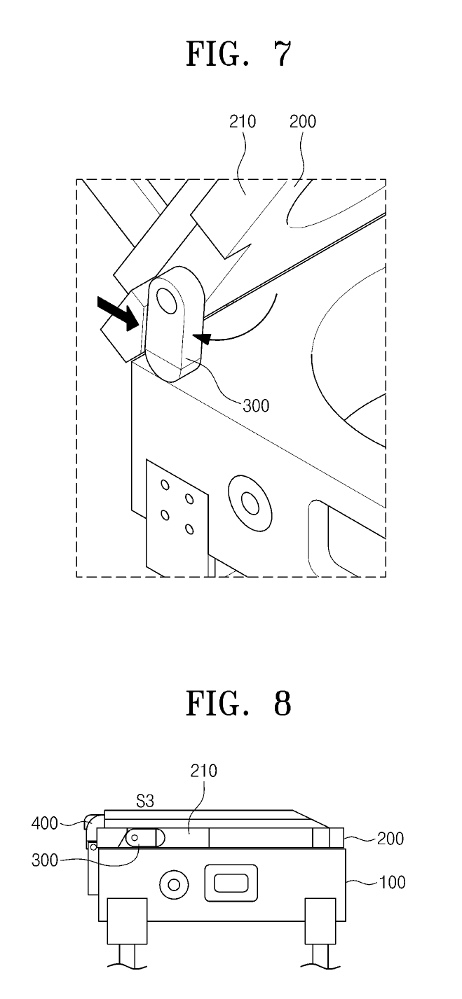

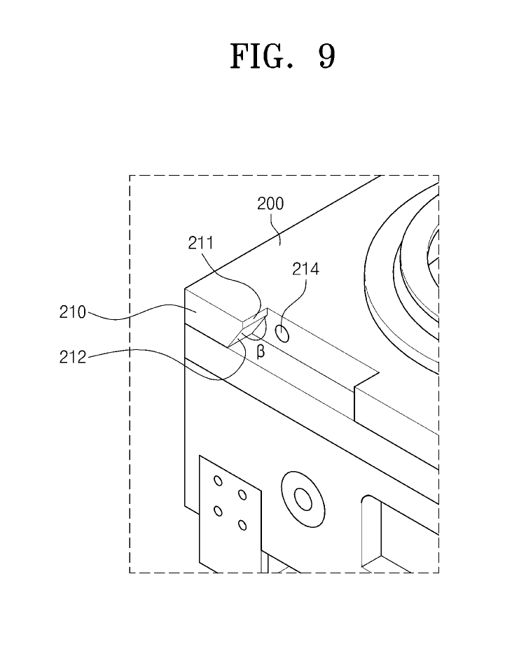

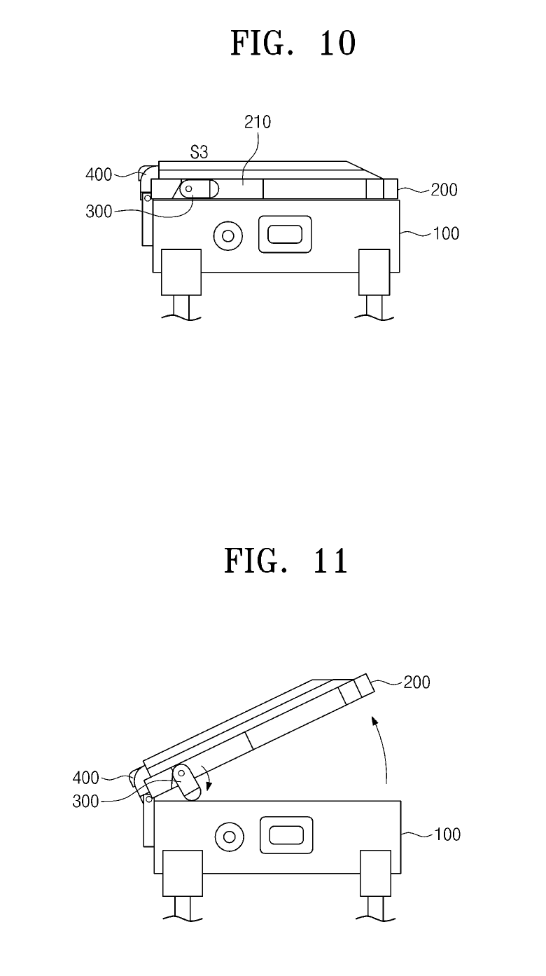

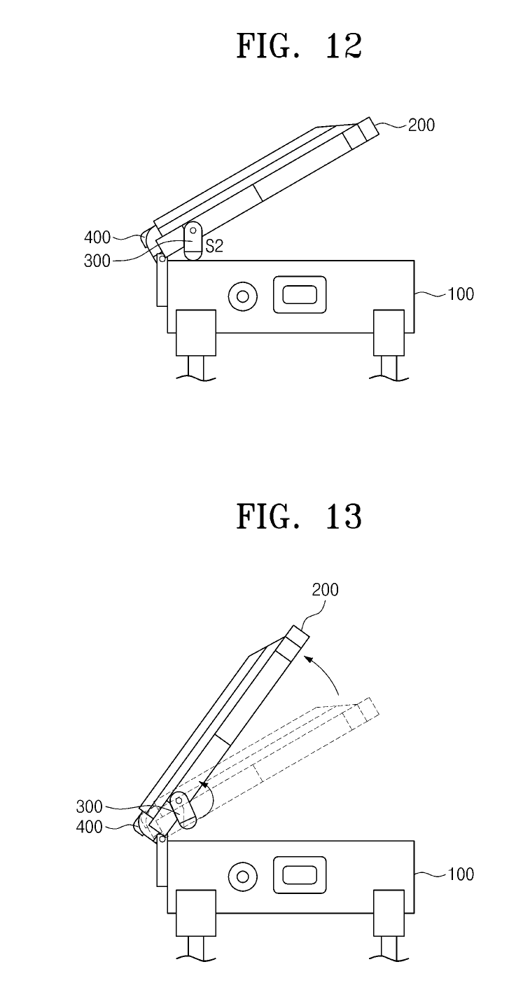

FIG. 3 is a perspective view illustrating a coupling configuration of a close preventing member in FIG. 2, FIG. 4 is a perspective view of a close preventing member in FIG. 3, FIG. 5 is a side view illustrating a first state of the close preventing member in FIG. 2, FIG. 6 is a side view illustrating a second state of the close preventing member in FIG. 2, FIG. 7 is a perspective view of FIG. 6, FIG. 8 is a side view illustrating a third state of the close preventing member in FIG. 2, and FIG. 9 illustrates a stopper in FIG. 3.

Referring to FIGS. 2 and 3, the cover member 200 opens/closes the processing chamber 100. The cover member 200 is coupled to the processing chamber 100 by a hinge part 400 to rotate upwardly and downwardly with respect to the hinge part 400. The baffle 800 forms a bottom surface of the cover member 200. The plasma generation chamber 140 is provided above the cover member 200.

The close preventing member 300 is installed on a sidewall 210 of the cover member 200. The close preventing member 300 prevents the cover member 200 from being closed during upward rotation of the cover member 200. That is, the close preventing member 300 supports the cover member 200 to prevent the cover member 200 from being closed while the processing chamber 100 is opened by upward rotation of the cover member 200.

A lower end of the close preventing member 300 is provided at a position where it overlaps an upper wall of the processing chamber 100 when viewed from the top. Accordingly, the lower end of the close preventing member 300 is placed on the upper wall of the processing chamber 100.

Referring to FIG. 3, the close preventing member 300 has an end which is pin-coupled to the sidewall 210 of the cover member 200. The other end of the close preventing member 300 is provided as a free end.

The sidewall 120 of the cover member 200 is provided such that an area provided with the close preventing member 300 is more recessed inwardly than an area corresponding to the hinge part 400. That is, a groove 213 is formed inwardly at a predetermined area on the sidewall 210 of the cover member 200 on which the close preventing member 300 is installed. A pin-coupling groove 214 is defined in the groove 213. A pin-coupling hole 301 corresponding to the pin-coupling groove 214 is defined in an end of the close preventing member 300. A pin 302 is inserted into the pin-coupling hole 301 and the pin-coupling groove 214, so that the end of the close preventing member 300 is coupled to the groove 213 defined in the sidewall 210 of the cover member 200.

Referring to FIG. 4, the close preventing member 300 includes a body part 310 and a supporting part 320. The body part 310 is provided on an end of the close preventing member 300. The supporting part 320 is provided on the other end of the close preventing member 300. The supporting member 320 supports the cover member 200 to prevent the cover member 200 from being closed when the processing chamber 100 is opened by upward rotation of the cover member 200. The supporting part 320 supports the cover member 200 while it is placed on an upper wall of the processing chamber 100.

The supporting part 320 is detachably coupled to the body part 310. The body part 310 is made of a material greater in strength than the supporting part 320. The body part 310 is made of stainless steel (SUS). The supporting part 320 is made of Teflon. Teflon based resin prevents scratches caused by friction and facilitates friction for sliding.

Accordingly, the supporting part 320 may be easily replaced when a service life thereof comes to an end due to abrasion, damage, etc. An end of the supporting part 320 may be rounded to smoothly support the cover member 200 during a rotation process.

Referring to FIGS. 5 and 6, the close preventing member 300 includes a first state S1 and a second state S2. As illustrated in FIG. 5, the supporting part 320 is disposed above the body part 310 in the first state S1. As illustrated in FIG. 6, the supporting part 320 is disposed below the body part 310 in the second state S2. The close preventing member 300 may be converted between the first state S1 and the second state S2. Conversion from the first state S1 to the second state S2 is performed by rotation of the close preventing member 300 with respect to the hinge part 400 by gravity.

Referring to FIGS. 6 and 7, the close preventing member 300 is provided vertically to a horizontal plane in the second state S2. A rotational angle (a) of the close preventing member 300 between the first state S1 and the second state S2 is greater than 180° and is equal to or less than 270°. The close preventing member 300 rotates clockwise from the first state S1 in FIG. 5 to the second state S2 in FIG. 6 with respect to the pin-coupling. Also, the close preventing member 300 rotates counterclockwise from the second state S2 in FIG. 6 to the first state S1 in FIG. 5 with respect to the pin-coupling. Here, the rotational angle (a) is greater than 180° and is equal to or less than 270°.

Referring to FIG. 8, when the cover member 200 completely rotates downwardly to close the processing chamber 100, the close preventing member 300 includes, between the first state S1 and the second state S2, a third state where the close preventing member 300 is disposed horizontally to the sidewall 210 of the cover member 200. In the third state S3, the close preventing member 300 is disposed, parallel to a longitudinal direction thereof, on an upper wall of the cover member 200. In the third state S3, the close preventing member 300 overlaps the sidewall 210 of the cover member 200 when viewed from the side.

Referring to FIG. 9, the substrate treating apparatus 10 has a first stopper 211 and a second stopper 212. The first stopper 211 and the second stopper 212 are provided on the sidewall 210 of the cover member 200. The first stopper 211 is provided vertically to an upper surface of the cover member 200. The second stopper 212 inclinedly extends from a lower end of the first stopper 211. The second stopper 212 is inclined downwardly towards the hinge part 400.

The first stopper 211 restricts a rotational range allowing the close preventing member 300 to rotate until the first state S1 when the cover member 200 rotates downwardly to close the processing chamber 100. The second stopper 212 restricts a rotational range allowing the close preventing member 300 to rotate until the second state S2 when the cover member 200 rotates upwardly to open the processing chamber 100. That is, the first stopper 211 and the second stopper 212 prevent the close preventing member 300 from exceeding predetermined upward/downward rotational ranges. An angle (β) between the first stopper 211 and the second stopper 212 according to a rotational direction of the close preventing member 300 is greater than 180° and is equal to or less than 270°.

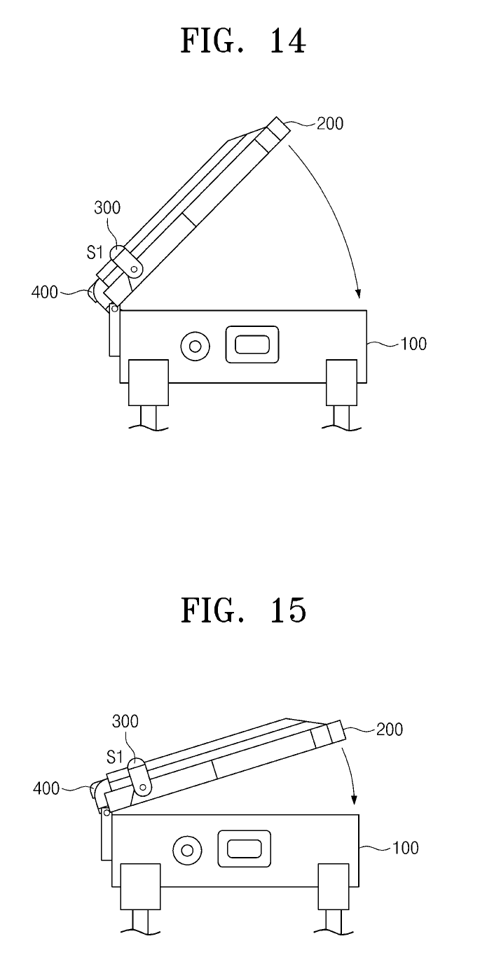

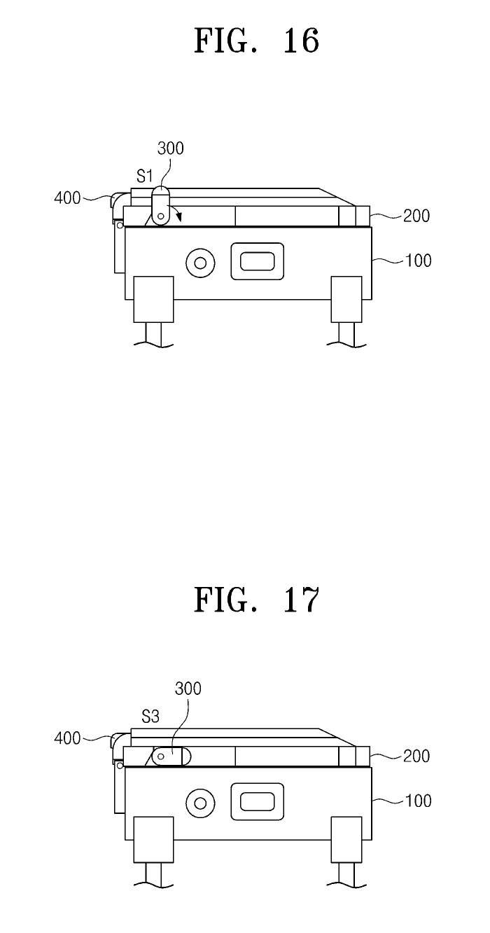

FIGS. 10 to 12 illustrate how the close preventing member is operated during opening of the cover member, and FIGS. 13 to 17 illustrate how the close preventing member is operated during closing of the cover member. Hereinafter, referring to FIGS. 10 to 17, a process that the close preventing member 300 is operated during the cover member 200 is opened/closed will be described.

FIG. 10 illustrates a state in which the cover member 200 closes the processing chamber 100. Here, the close preventing member 300 is in the third state S3 and is disposed horizontally to the sidewall 210 of the cover member 200. In FIG. 11, when the cover member 200 rotates upwardly with respect to the hinge part 400 to begin to open the processing chamber 100, the close preventing member 300 rotates downwardly in a clockwise direction by gravity. After that, when upward rotation of the cover member 200 is completed as illustrated in FIG. 12, downward rotation of the close preventing member 300 is also completed to contact the second stopper 212, thereby maintaining the second state S2. Here, the supporting part 320 of the close preventing member 300 is disposed on the upper wall of the processing chamber 100 to support the cover member 200, thereby preventing the cover member 200 from being closed.

When the cover member 200 is closed after an operation such as maintenance is completed in FIG. 12, As illustrated in FIG. 13, the cover member 200 is lifted at a predetermined height to detach the supporting part 320 of the close preventing member 300 from the upper wall of the processing chamber 100.

Then, as illustrated in FIGS. 13 and 14, the close preventing member 300 is converted from the second state S2 to the first state S1 before downward rotation of the cover member 200 begins. Here, conversion from the second state S2 to the first state S1 of the closing preventing member 300 may be performed by external force. For example, the external force may be provided by operation of an operator. The close preventing member 300 rotates counterclockwise from the second state S2 to be in contact with the first stopper 211, thereby maintaining the first state S1. This prevents the close preventing member 300 from disturbing closing of the cover member 200.

As illustrated in FIGS. 15 and 16, the close preventing member 300 continues to maintain the first state S1 during downward rotation of the cover member 200. In FIG. 17, when the cover member 200 completely rotates downwardly to close the processing chamber 100, the close preventing member 300 is converted from the first state S1 to the third state S3. Conversion from the first state S1 to the third state S3 of the close preventing member 300 may be performed by gravity. That is, the state is converted by own weight of the close preventing member 300

The present invention having the above-described configuration and operation process prevents the cover member 200 opening/closing the processing chamber 100 from being suddenly closed to secure operator's safety. Also, the present invention has the close prevention member 300 with a simplified structure to promote operation convenience and also prevent in advance an accident caused by missing of safety apparatus operation malfunctions of a gas spring, an actuator, or a fixing pin, or operation mistake.

A substrate treating apparatus according to an embodiment of the present invention may prevent a cover member opening/closing a processing chamber from being sudden closed to secure operator's safety.

Also, the substrate treating apparatus according to an embodiment of the present invention has a close preventing member with a simplified structure to promote operation convenience and also prevent in advance an accident caused by missing of safety apparatus operation.

The object of the present invention is not limited to the aforesaid, but other objects not described herein will be clearly understood by those skilled in the art from descriptions below.

Although embodiments have been described with reference to a number of illustrative embodiments thereof, it should be understood that numerous other modifications and embodiments can be devised by those skilled in the art that will fall within the spirit and scope of the principles of this disclosure. The invention may, however, be embodied in many different forms and should not be construed as being limited to the embodiments set forth herein. Rather, these embodiments are provided so that this disclosure will be thorough and complete, and will fully convey the concept of the invention to those skilled in the art. Hence, the real protective scope of the present invention shall be determined by the technical scope of the accompanying claims. Further, the appended claims should be appreciated as a step including even another embodiment

What is claimed is:

1. A substrate treating apparatus, comprising:
a processing chamber having an inner space in which process treatment is performed on a substrate;
a cover member coupled to the processing chamber by a hinge part and rotating upwardly and downwardly with respect to the hinge part to open/close the processing chamber; and
a close preventing member disposed on a sidewall of the cover member to prevent the cover member from being closed during upward rotation of the cover member.

2. The substrate treating apparatus of claim 1, wherein the close preventing member has a lower end which is provided at a position where it overlaps an upper wall of the processing chamber when viewed from the top.

3. The substrate treating apparatus of claim 1, wherein the close preventing member has an end which is pin-connected to a sidewall of the cover member, and the other end provided as a free end.

4. The substrate treating apparatus of claim 3, wherein the close preventing member comprises a body part providing the end, and a supporting part providing the other end.

5. The substrate treating apparatus of claim 4, wherein the close preventing member is convertible between a first state where the supporting part is disposed above the body part and a second state where the supporting part is disposed below the body part,
wherein the conversion from the first state to the second state is performed by rotation of the close preventing member with respect to the hinge part by gravity.

6. The substrate treating apparatus of claim 5, wherein the close preventing member is provided vertically to a horizontal plane in the second state, and a rotational angle of the close preventing member between the first state and the second state is greater than 180° and is equal to or less than 270°.

7. The substrate treating apparatus of claim 6, wherein the close preventing member further includes, between the first state and the second state, a third state where the close preventing member is disposed horizontally to a sidewall of the cover member, when the cover member completely rotates downwardly to close the processing chamber.

8. The substrate treating apparatus of claim 7, wherein the close preventing member is converted from the second state to the first state before downward rotation of the cover member, maintains the first state during the downward rotation of the cover member, and is converted from the first state to the third state when the downward rotation of the cover member is completed to close the processing chamber.

9. The substrate treating apparatus of claim 8, wherein the conversion from the second state to the first state is performed by external force.

10. The substrate treating apparatus of claim 2, wherein the sidewall of the cover member is provided such that an area provided with the close preventing member is more recessed inwardly than an area corresponding to the hinge part.

11. The substrate treating apparatus of claim 4, comprising:
a first stopper restricting rotational range allowing the close preventing member to rotate until the first state when the cover member rotates downwardly to close the processing chamber; and
a second stopper restricting rotational range allowing the close preventing member to rotate until the second state when the cover member rotates upwardly to open the processing chamber.

12. The substrate treating apparatus of claim 11, wherein the first stopper and the second stopper are provided on the sidewall of the cover member.

13. The substrate treating apparatus of claim 11, wherein the first stopper is provided vertically to a top surface of the cover member, and the second stopper extends from a lower end of the first stopper, wherein an angle between the first stopper and the second stopper according to a rotational direction of the close preventing member is greater than 180° and is equal to or less than 270°.

14. The substrate treating apparatus of claim 4, wherein the supporting part is detachably coupled to the body part.

15. The substrate treating apparatus of claim 4, wherein the body part is made of a material greater in strength than the supporting part.

16. The substrate treating apparatus of claim 15, wherein the body part is made of stainless steel and the supporting part is made of Teflon.
